(19) United States
(12) Patent Application Publication
(10) Pub. No.: US 2025/0254849 A1
(43) Pub. Date: Aug. 7, 2025

(54) ENCAPSULATION AND WATER VAPOR REMOVAL DEVICE, ENCAPSULATING METHOD OF DISPLAY PANEL, AND DISPLAY DEVICE

(71) Applicant: HKC CORPORATION LIMITED, Shenzhen (CN)

(72) Inventors: HONGSONG WANG, Shenzhen (CN); Haijiang Yuan, Shenzhen (CN)

(21) Appl. No.: 19/045,579

(22) Filed: Feb. 5, 2025

(30) Foreign Application Priority Data
Feb. 7, 2024 (CN) 202410171681.1

(51) Int. Cl. H05K 7/20

(52) U.S. Cl. CPC H05K 7/20972

(57) ABSTRACT

An encapsulation and water vapor removal device, an encapsulating method of a display panel, and a display device are disclosed. The display panel includes a substrate, a pixel module, and a cover plate. The pixel module is arranged on the substrate. The cover plate is arranged on a side of the pixel module facing away from the substrate. An encapsulation and water vapor removal device is arranged on a side of the pixel module. The encapsulation and water vapor removal device is used to remove water vapor between the substrate and the cover plate. After the water vapor is discharged, a sealant is injected to seal the sides of the substrate and the cover plate to obtain an encapsulated display panel.

### CROSS-REFERENCE TO RELATED APPLICATIONS

This application claims the priority and benefit of Chinese patent application number 2024101716811, titled “Encapsulation and water vapor removal device, Encapsulating Method of Display Panel, and Display Device” and filed Feb. 7, 2024 with China National Intellectual Property Administration, the entire contents of which are incorporated herein by reference.

### TECHNICAL FIELD

This application relates to the field of display technology, and more particularly relates to an encapsulation and water vapor removal device, an encapsulating method of a display panel, and a display device.

### BACKGROUND

The description provided in this section is intended for the mere purpose of providing background information related to the present application but doesn't necessarily constitute prior art.

Organic light-emitting diodes (OLEDs) have the characteristics of self-luminescence, high brightness, wide viewing angle, high contrast, flexibility, and low energy consumption. Therefore, OLED display technology is widely used in mobile phone screens, computer monitors, full-color TVs, etc. The display area of a display panel based on OLED devices may include a substrate, an anode arranged on the substrate, a hole injection layer arranged on the anode, a hole transport layer arranged on the hole injection layer, a light-emitting layer arranged on the hole transport layer, an electron transport layer arranged on the light-emitting layer, an electron injection layer arranged on the electron transport layer, and a cathode arranged on the electron injection layer, thereby forming a plurality of sub-pixels. The light-emitting principle of OLED display panel is that a semiconductor material and an organic light-emitting material emit light through carrier injection and recombination under the drive of an electric field.

The light-emitting layer material and the cathode material are sensitive to water and oxygen, and environmental impurities will also affect the life of OLED devices. Therefore, it is necessary to effectively seal the OLED device, especially in an environment with complex airflow and water vapor conditions. The water vapor in the air makes it difficult to control the encapsulating process of the encapsulating material fluid under vacuum conditions, and there will be bubbles in non-vacuum conditions. Therefore, the above problems need to be solved urgently.

### SUMMARY

In view of the above, it is one purpose of the present application to provide an encapsulation and water vapor removal device, a display panel, and an encapsulating method for the display panel, which extend the water vapor intrusion path and improve the encapsulation effect.

The present application discloses an encapsulation and water vapor removal device for a display panel. The display panel includes a substrate, a pixel module, and a cover plate. The pixel module is arranged on the substrate. The cover plate is arranged on a side of the pixel module facing away from the substrate. The encapsulation and water vapor removal device is arranged on a side of the pixel module. The encapsulation and water vapor removal device is used to remove water vapor between the substrate and the cover plate. After the water vapor is discharged, a sealant is injected to seal the sides of the substrate and the cover plate to obtain an encapsulated display panel.

In some embodiments, the encapsulation and water vapor removal device includes an air intake and discharge device and a control mechanism. The air intake and discharge device includes a first power assembly, a second power assembly, an air inlet, and an air outlet. The air inlet is arranged on a side of the first power assembly adjacent to the pixel module. The air outlet is arranged on a side of the first power assembly facing away from the air inlet. The second power assembly is arranged between the first power assembly and the air outlet. The control mechanism is arranged on one side of the air intake and discharge device, and is signal-connected to each of the first power assembly and the second power assembly. When the air intake and discharge device is in an intake state, the control mechanism controls the first power assembly to suck in air from between the substrate and the cover plate through the air inlet. When the air intake and discharge device is in a discharge state, the control mechanism controls the second power assembly to discharge air with water vapor to the outside of the air intake and discharge device away from the display panel.

In some embodiments, the air intake and discharge device further includes a first airflow channel, a second airflow channel, and a third airflow channel arranged in sequence. The first power assembly includes a first engagement switch and a first pressure structure. The second power assembly includes a second engagement switch, a second pressure structure, and a third engagement switch. The first engagement switch is arranged on a side adjacent to the pixel module. The third engagement switch is arranged on a side adjacent to the air outlet. The second engagement switch is arranged between the first engagement switch and the third engagement switch. The first pressure structure is arranged between the first engagement switch and the second engagement switch. The second pressure structure is arranged between the second engagement switch and the third engagement switch.

The air inlet is connected to the second airflow channel through the first airflow channel and the first engagement switch. One end of the third airflow channel is connected to the second airflow channel through the second engagement switch. The other end of the third airflow channel is connected to the air outlet through the third engagement switch. The control mechanism controls the first pressure structure to drive the first engagement switch to be opened or closed. The control mechanism controls the second pressure structure to drive the second engagement switch and the third engagement switch to be opened or closed.

In some embodiments, the encapsulation and water vapor removal device further includes a fixing structure. The fixing structure includes a first fixing seat and a second fixing seat. The first fixing seat is arranged opposite to the second fixing seat to form the first airflow channel, the second airflow channel, and the third airflow channel. The first fixing seat and the second fixing seat each include a plurality of grooves, and the plurality of grooves are correspondingly and oppositely arranged to form the first accommodating chamber, the second accommodating chamber, the third accommodating chamber, the fourth accommodating chamber, and the fifth accommodating chamber. The first engagement switch is arranged in the first accommodating chamber. The first pressure structure is arranged in the second accommodating chamber and is connected to the second airflow channel through a first through hole. The second engagement switch is arranged in the third accommodating chamber. The second pressure structure is arranged in the fourth accommodating chamber and is connected to the third airflow channel through a second through hole. The third engagement switch is arranged in the fifth accommodating chamber. The first power assembly further includes a first power tube. The second power assembly further includes a second power tube and a third power tube. The first pressure structure controls the first engagement switch to be opened or closed through the first power tube. The second pressure structure controls the second engagement switch to be opened or closed through the second power tube. The second pressure structure controls the third engagement switch to be opened or closed through the third power tube.

In some embodiments, the second accommodating chamber includes a first cavity, a second cavity, and a third cavity connected in sequence. The first pressure structure includes a first fixing piece, a first piston air guide cushion, a first fixing plate, a first spring, a first electromagnet, and a first guide plate. The first fixing piece is arranged in the first cavity and is fixedly fitted with the first cavity to form the first through hole. The first fixing plate is arranged on the side of the first fixing piece adjacent to the second cavity and is slidably fitted a the cavity wall of the first cavity. The first piston air guide cushion is arranged on the side of the first fixing piece adjacent to the first fixing plate. The first guide plate is arranged on the side of the first fixing plate facing away from the first piston air guide cushion. A first power cavity is formed between the first piston air guide cushion and the first fixing plate.

The first electromagnet is arranged in the third cavity and fixedly connected to a cavity wall of the third cavity. The first spring is arranged in the second cavity. One end of the first spring is connected to the first guide plate, and the other end is connected to the first electromagnet. The first power cavity is connected to the first engagement switch through the first power tube.

The fourth accommodating chamber includes a fourth cavity, a fifth cavity, and a sixth cavity connected in sequence. The second pressure structure includes a second fixing piece, a second piston air guide cushion, a second fixing plate, a second spring, a second electromagnet, and a second guide plate. The second fixing piece is arranged in the sixth cavity and fixedly fitted with the sixth cavity to form the second through hole. The second fixing plate is arranged on the side of the second fixing piece adjacent to the fifth cavity and is slidably fitted with a cavity wall of the sixth cavity. The second piston air guide cushion is arranged on the side of the second fixing piece adjacent to the second fixing plate. The second guide plate is arranged on the side of the second fixing plate facing away from the second piston air guide cushion. A second power cavity is formed between the second piston air guide cushion and the second fixing plate.

The second electromagnet is arranged in the fourth cavity and fixedly connected to a cavity wall of the fourth cavity. The second spring is arranged in the fifth cavity. One end of the second spring is connected to the second guide plate, and the other end is connected to the second electromagnet. The second power cavity is connected to the second engagement switch through the second power tube. The second power cavity is further connected to the third engagement switch through the third power tube.

In some embodiments, the first engagement switch includes a first push piece, a first retractable piece, a second retractable piece, and a second push piece. The first retractable piece and the second retractable piece are arranged opposite to each other. The first push piece is arranged on a side of the first retractable piece facing away from the second retractable piece, and is fixedly connected to the first retractable piece. The second push piece is arranged on the side of the second retractable piece facing away from the first retractable piece, and is fixedly connected to the second retractable piece.

The first accommodating chamber includes a first sub-chamber, a second sub-chamber, a third sub-chamber, and a fourth sub-chamber. The first push piece is arranged in the first sub-chamber, and is slidably fitted with the first sub-chamber. The first retractable piece is arranged in the second sub-chamber, and is slidably fitted with the second sub-chamber. The second retractable piece is arranged in the third sub-chamber and is slidably fitted with the third sub-chamber. The second push piece is arranged in the fourth sub-chamber and is slidably fitted with the fourth sub-chamber.

The first power tube includes a first sub-power tube and a second sub-power tube. The first sub-chamber is connected to the first power cavity through the first sub-power tube. The fourth sub-chamber is connected to the first power cavity through the second sub-power tube.

The second engagement switch includes a third push piece, a third retractable piece, a fourth retractable piece, and a fourth push piece. The third retractable piece and the fourth retractable piece are arranged opposite to each other. The third push piece is arranged on the side of the third retractable piece facing away from the fourth retractable piece, and is fixedly connected to the third retractable piece. The fourth push piece is arranged on the side of the fourth retractable piece facing away from the third retractable piece, and is fixedly connected to the third retractable piece.

The third accommodating chamber includes a fifth sub-chamber, a sixth sub-chamber, a seventh sub-chamber, and an eighth sub-chamber. The third push piece is arranged in the fifth sub-chamber, and is slidably fitted with the fifth sub-chamber. The third retractable piece is arranged in the sixth sub-chamber, and is slidably fitted with the sixth sub-chamber. The fourth retractable piece is arranged in the seventh sub-chamber and is slidably fitted with the seventh sub-chamber. The fourth push piece is arranged in the eighth sub-chamber and is slidably fitted with the eighth sub-chamber.

The second power tube includes a third sub-power tube and a fourth sub-power tube. The fifth sub-chamber is connected to the second power cavity through the third sub-power tube. The eighth sub-chamber is connected to the second power cavity through the fourth sub-power tube.

The third engagement switch includes a fifth push piece, a fifth retractable piece, a sixth retractable piece, and a sixth push piece. The fifth retractable piece and the sixth retractable piece are arranged opposite to each other. The fifth push piece is arranged on the side of the fifth retractable piece facing away from the sixth retractable piece, and is fixedly connected to the sixth retractable piece. The sixth push piece is arranged on the side of the sixth retractable piece facing away from the fifth retractable piece, and is fixedly connected to the sixth retractable piece.

The fifth accommodating chamber includes a ninth sub-chamber and a tenth sub-chamber. The fifth push piece and the fifth retractable piece are both arranged in the ninth sub-chamber and are slidably fitted with the ninth sub-chamber. The fifth push piece is fitted with the ninth sub-chamber to form a first push chamber. The sixth retractable piece and the sixth push piece are both arranged in the tenth sub-chamber and are slidably fitted with the tenth sub-chamber. The sixth push piece is fitted with the tenth sub-chamber to form a second push chamber. The third power tube includes a fifth sub-power tube and a sixth sub-power tube. The first push chamber is connected to the second power cavity through the fifth sub-power tube. The second push chamber is connected to the second power cavity through the sixth sub-power tube.

In some embodiments, the first pressure structure further includes a first auxiliary assembly, which is arranged in the second accommodating chamber and pressed against the first fixing plate. The second pressure structure further includes a second auxiliary assembly, which is arranged in the fourth accommodating chamber and pressed against the second fixing plate.

In some embodiments, the encapsulation and water vapor removal device is a cylindrical structure. The substrate includes a first fixing end on one side adjacent to the encapsulation and water vapor removal device. The cover plate includes a second fixing end on one side adjacent to the encapsulation and water vapor removal device. An opening is formed between the first fixing end and the second fixing end. The encapsulation and water vapor removal device is installed in the opening. The first fixing piece fixedly abuts against the first fixing end, and the second fixing piece fixedly abuts against the second fixing end. The encapsulation and water vapor removal device further includes a first sealing piece and a second sealing piece.

The encapsulation and water vapor removal device further includes a first sealing piece and a second sealing piece. The first sealing piece is connected to the second sealing piece. The second fixing end includes a fixing end body, an adhesive injection channel, and an adhesive injection port. The adhesive injection port is arranged on a side of the fixing end body away from the first sealing piece. The adhesive injection channel penetrates through the fixing end body. The adhesive injection port is connected to the first sealing piece through the adhesive injection channel.

The present application further discloses an encapsulating method for a display panel, which is used for the display panel as described above, and includes the following operations:
forming a pixel module on a substrate;
forming an encapsulation layer on the pixel module;
disposing a cover plate above the encapsulation layer;
installing an encapsulation and water vapor removal device on a side of
the pixel module;
using a sensor for detection;
if the sensor detects that there is water vapor between the substrate and the cover plate, a control mechanism controlling a first pressure structure to open the first engagement switch for suction;
after the suction is completed, the first pressure structure closing the first engagement switch, the control mechanism controlling the second pressure structure to open the second engagement switch for suction, and the second pressure structure opening the third engagement switch for discharge;
after the discharge is completed, when the sensor cannot detect water vapor, permanently closing the first engagement switch and the second engagement switch;
injecting an encapsulation adhesive from the adhesive injection port in the cover plate to seal the sides of the display panel to obtain an encapsulated display panel.

The present application further discloses a display device, including the above-mentioned display panel.

Compared with the solution in the related art that the encapsulation of the display panel is only carried out in a vacuum state or a non-vacuum state, on the side of the pixel module of the display panel of the present application is disposed an encapsulation and water vapor removal device, which is used to remove the water vapor between the substrate and the cover plate. In this way, after the inorganic material encapsulation, the encapsulation and water vapor removal device can be used to discharge the water vapor between the substrate and the cover plate to reduce the influence of the water vapor in the display panel on the pixel module. After the water vapor is discharged, the sealant is injected to seal the sides of the substrate and the cover plate to obtain the encapsulated display panel. In this way, the water vapor path that may exist on the exterior of the display panel is sealed and isolated, thereby improving the overall encapsulation effect of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram illustrating a cross-sectional structure of a display panel according to an embodiment of the present application.

FIG. 2 is a schematic diagram illustrating a cross-sectional structure of an encapsulation and water vapor removal device in a suction state according to an embodiment of the present application.

FIG. 3 is a partial enlarged schematic diagram of portion A shown in FIG. 2.

FIG. 4 is a partial enlarged schematic diagram of portion B shown in FIG. 2.

FIG. 5 is a partial enlarged schematic diagram of portion C shown in FIG. 2.

FIG. 6 is a schematic diagram illustrating a cross-sectional structure of an encapsulation and water vapor removal device in a discharge state according to an embodiment of the present application.

FIG. 7 is a partial enlarged schematic diagram of portion D shown in FIG. 6.

FIG. 8 is a partial enlarged schematic diagram of portion E shown in FIG. 6.

FIG. 9 is a partial enlarged schematic diagram of portion F shown in FIG. 6.

FIG. 10 is a flowchart of an encapsulating method for a display panel according to an embodiment of the present application.

FIG. 11 is a block diagram of a display device according to an embodiment of the present application.

In the drawings: 10, display device; 100, display panel; 110, substrate; 111, first fixing end; 120, pixel module; 130, cover plate; 131, second fixing end; 132, fixing end body; 133, adhesive injection channel; 134, adhesive injection port; 200, encapsulation and water vapor removal device; 210, air intake and discharge device; 220, control mechanism; 221, first control module; 222, second control module; 230, first power assembly; 231, first power tube; 232, first sub-power tube; 233, second sub-power tube; 240, second power assembly; 241, second power tube; 242, third power tube; 243, third sub-power tube; 244, fourth sub-power tube; 245, fifth sub-power tube; 246, sixth sub-power tube; 250, air inlet; 260, air outlet; 270, first airflow channel; 280, second airflow channel; 290, third airflow channel; 300, first engagement switch; 301, first push piece; 302, first retractable piece; 303, second retractable piece; 304, second push piece; 305, first air intake channel; 310, first pressure structure; 311, first fixing piece; 312, first piston air guide cushion; 313, first fixing plate; 314, first spring; 315, first electromagnet; 316, first guide plate; 317, first auxiliary pressing rod; 318, second auxiliary pressing rod; 319, first fulcrum; 320, second fulcrum; 321, first auxiliary pressure pipe; 322, second auxiliary pressure pipe; 323, first pressure valve; 324, second pressure valve; 400, second engagement switch; 401, third push piece; 402, third retractable piece; 403, fourth retractable piece; 404, fourth push piece; 405, second air intake channel; 410, second pressure structure; 411, second fixing piece; 412, second piston air guide cushion; 413, second fixing plate; 414, second spring; 415, second electromagnet; 416, second guide plate; 417, third auxiliary pressing rod; 418, fourth auxiliary pressing rod; 419, third fulcrum; 420, fourth fulcrum; 421, third auxiliary pressure pipe; 422, fourth auxiliary pressure pipe; 423, third pressure valve; 424, fourth pressure valve; 430, third engagement switch; 431, fifth push piece; 432, fifth retractable piece; 433, sixth retractable piece; 434, sixth push piece; 435, discharge channel; 500, fixing structure; 510, first fixing seat; 520, second fixing seat; 530, first accommodating chamber; 531, first sub-chamber; 532, second sub-chamber; 533, third sub-chamber; 534, fourth sub-chamber; 540, second accommodating chamber; 541, first through hole; 542, first cavity; 543, second cavity; 544, third cavity; 550, third accommodating chamber; 551, fifth sub-chamber; 552, sixth sub-chamber; 553, seventh sub-chamber; 554, eighth sub-chamber; 555, second through hole; 560, fourth accommodating chamber; 561, fourth cavity; 562, fifth cavity; 563, sixth cavity; 570, fifth accommodating chamber; 571, ninth sub-chamber; 572, tenth sub-chamber; 573, first push chamber; 574, second push chamber; 600, first power cavity; 610, second power cavity; 620, first protrusion; 630, second protrusion; 640, third protrusion; 650, fourth protrusion; 700, opening; 710, first sealing piece; 720, first sealing column; 730, first sealing groove; 800, second sealing piece; 810, second sealing column; 820, second sealing groove; 900, internal gas collection chamber; 910, sensor.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

The present application will be described in detail below with reference to the accompanying drawings and some optional embodiments.

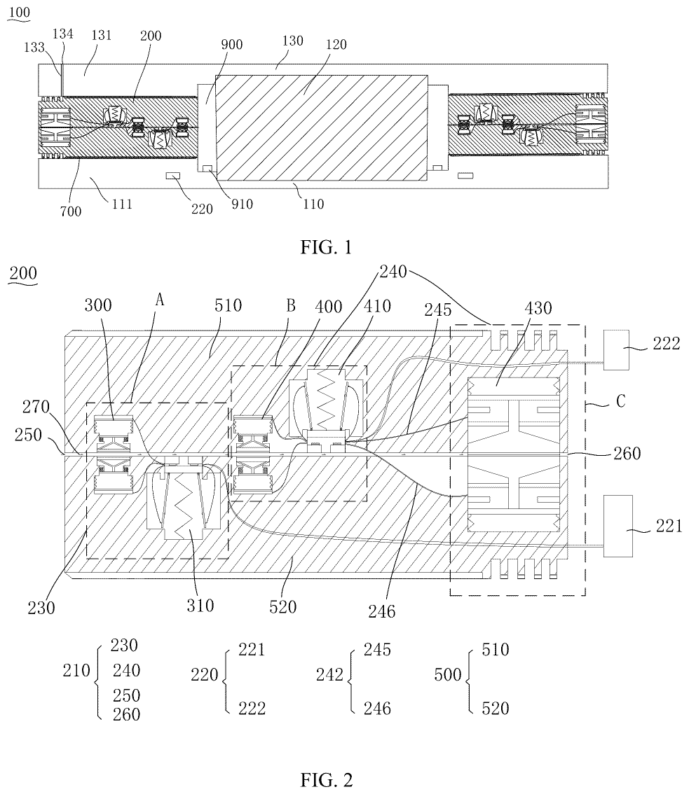

FIG. 1 is a schematic diagram illustrating a cross-sectional structure of a display panel according to an embodiment of the present application. The present application discloses an encapsulation and water vapor removal device 200 for a display panel 100. The display panel 100 includes a substrate 110, a pixel module 120, and a cover plate 130. The pixel module 120 is arranged on the substrate 110. The cover plate 130 is arranged on the side of the pixel module 120 facing away from the substrate 110. The encapsulation and water vapor removal device 200 is arranged on a side of the pixel module 120. The encapsulation and water vapor removal device 200 is used to remove water vapor between the substrate 110 and the cover plate 130. After the water vapor is discharged, a sealant is injected to seal the sides of the substrate 110 and the cover plate 130 to obtain the encapsulated display panel 100.

Compared with the solution in the related art that the encapsulation of the display panel 100 is only carried out in a vacuum state or a non-vacuum state, on the side of the pixel module 120 of the display panel 100 of the present application is disposed an encapsulation and water vapor removal device 200, which is used to remove the water vapor between the substrate 110 and the cover plate 130. In this way, after the inorganic material encapsulation, the encapsulation and water vapor removal device 200 can be used to discharge the water vapor between the substrate 110 and the cover plate 130 to reduce the influence of the water vapor in the display panel 100 on the pixel module 120. After the water vapor is discharged, the sealant is injected to seal the sides of the substrate 110 and the cover plate 130 to obtain the encapsulated display panel 100. In this way, the water vapor path that may exist on the exterior of the display panel 100 is sealed and isolated, thereby improving the overall encapsulation effect of the display panel 100.

FIG. 2 is a schematic diagram illustrating a cross-sectional structure of an encapsulation and water vapor removal device under a suction state according to an embodiment of the present application. As shown in FIG. 2, the encapsulation and water vapor removal device 200 includes an air intake and discharge device 210 and a control mechanism 220. The air intake and discharge device 210 includes a first power assembly 230, a second power assembly 240, an air inlet 250, and an air outlet 260. The air inlet 250 is arranged on the side of the first power assembly 230 adjacent to the pixel module 120. The air outlet 260 is arranged on the side of the first power assembly 230 facing away from the air inlet 250. The second power assembly 240 is arranged between the first power assembly 230 and the air outlet 260. The control mechanism 220 is arranged on one side of the air intake and discharge device 210, and is in a signal connection with each of the first power assembly 230 and the second power assembly 240. When the air intake and discharge device 210 is in an intake state, the control mechanism 220 controls the first power assembly 230 to suck in air from between the substrate 110 and the cover plate 130 through the air inlet 250. When the air intake and discharge device 210 is in a discharge state, the control mechanism 220 controls the second power assembly 240 to discharge the air with water vapor to the outer side of the air intake and discharge device 210 facing away from the display panel 100. The control mechanism 220 includes a first control module 221 and a second control module 222. The first control module 221 controls the first power assembly 230. The second control module 222 controls the second power assembly 240.

As shown in FIG. 1, the display panel 100 further includes an internal gas collection chamber 900 and a sensor 910. The internal gas collection chamber 900 is disposed between the pixel module 120 and the encapsulation and water vapor removal device 200. The sensor 910 is disposed in the internal gas collection chamber 900. The sensor 910 is signal-connected to each of the first control module 221 and the second control module 222. When the sensor 910 detects that water vapor exists in the internal gas collection chamber 900, a signal is transmitted to each of the first control module 221 and the second control module 222. The first control module 221 and the second control module 222 each receive the signal and drive the encapsulation and water vapor removal device 200 to be turned on. The existence of the internal gas collection chamber 900 can also prevent the encapsulation and water vapor removal device 200 from sucking both sides of the display panel 100 during the suction process thereby blocking the flow of air.

Specifically, as shown in FIG. 2, the air intake and discharge device 210 further includes a first airflow channel 270, a second airflow channel 280, and a third airflow channel 290 that arranged in sequence. The first power assembly 230 includes a first engagement switch 300 and a first pressure structure 310. The second power assembly 240 includes a second engagement switch 400, a second pressure structure 410, and a third engagement switch 430. The first engagement switch 300 is arranged on a side adjacent to the pixel module 120. The third engagement switch 430 is arranged on a side adjacent to the air outlet 260. The second engagement switch 400 is arranged between the first engagement switch 300 and the third engagement switch 430. The first pressure structure 310 is arranged between the first engagement switch 300 and the second engagement switch 400. The second pressure structure 410 is arranged between the second engagement switch 400 and the third engagement switch 430. The air inlet 250 is connected to the second airflow channel through the first airflow channel 270 and the first engagement switch 300. One end of the third airflow channel is connected to the second airflow channel 280 through the second engagement switch 400. The other end of the third airflow channel 290 is connected to the air outlet 260 through the third engagement switch 430. The first control module 221 controls the first pressure structure 310 to drive the first engagement switch 300 to be opened or closed. The second control module 222 controls the second pressure structure 410 to drive the second engagement switch 400 and the third engagement switch 430 to open or close for air intake or discharge.

For fixing and installation, the encapsulation and water vapor removal device 200 further includes a fixing structure 500. The fixing structure 500 includes a first fixing seat 510 and a second fixing seat 520. The first fixing seat 510 is arranged opposite to the second fixing seat 520 to form the first airflow channel 270, the second airflow channel 280, and the third airflow channel 290. The first fixing seat 510 and the second fixing seat 520 each include a plurality of grooves. The plurality of grooves are oppositely arranged to form a first accommodating chamber 530, a second accommodating chamber 540, a third accommodating chamber 550, a fourth accommodating chamber 560, and a fifth accommodating chamber 570. The first engagement switch 300 is arranged in the first accommodating chamber 530. The first pressure structure 310 is disposed in the second accommodating chamber 540 and is connected to the second airflow channel 280 through a first through hole 541. The second engagement switch 400 is disposed in the third accommodating chamber 550. The second pressure structure 410 is disposed in the fourth accommodating chamber 560 and is connected to the third airflow channel 290 through a second through hole 555. The third engagement switch 430 is disposed in the fifth accommodating chamber 570.

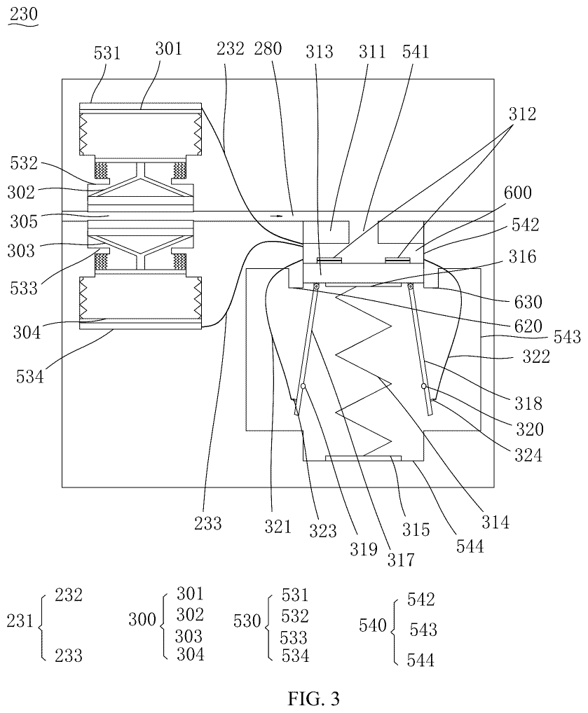

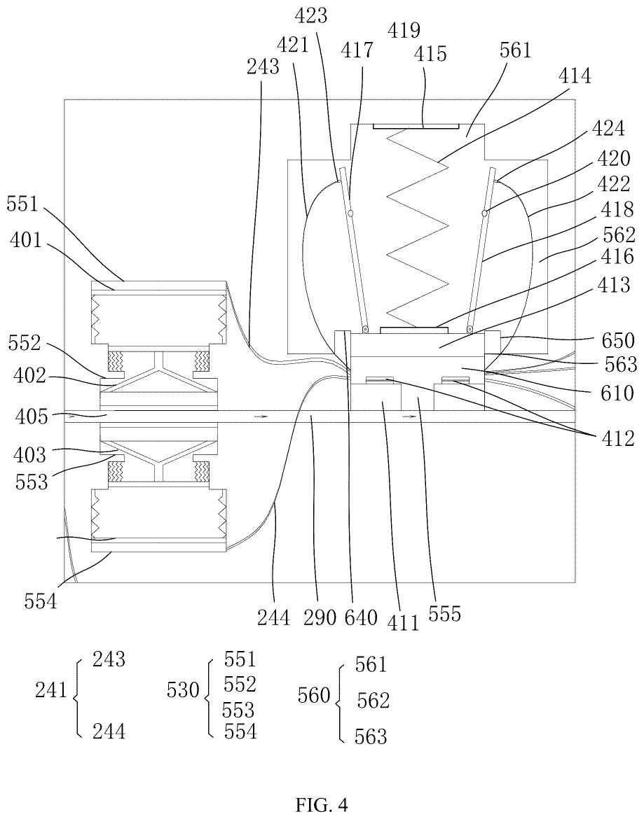

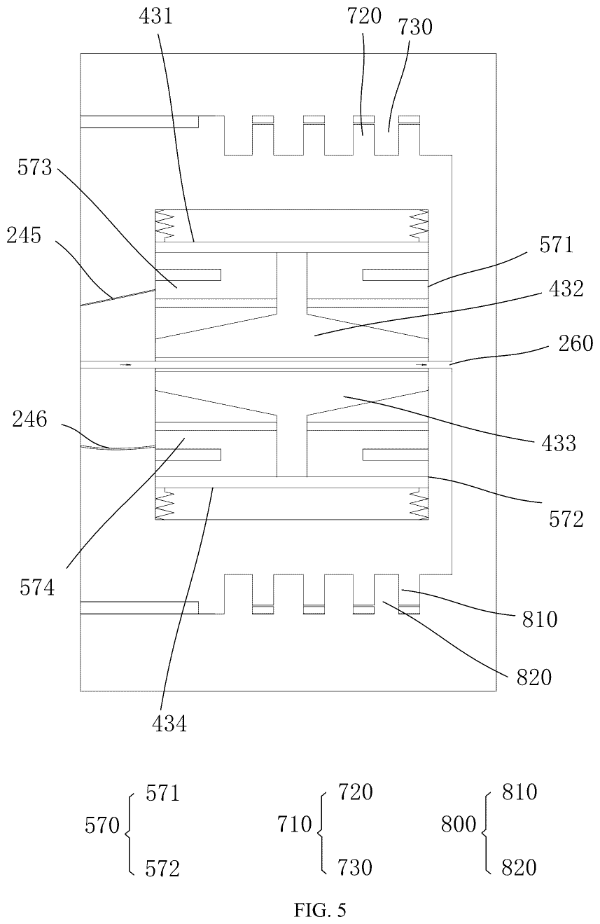

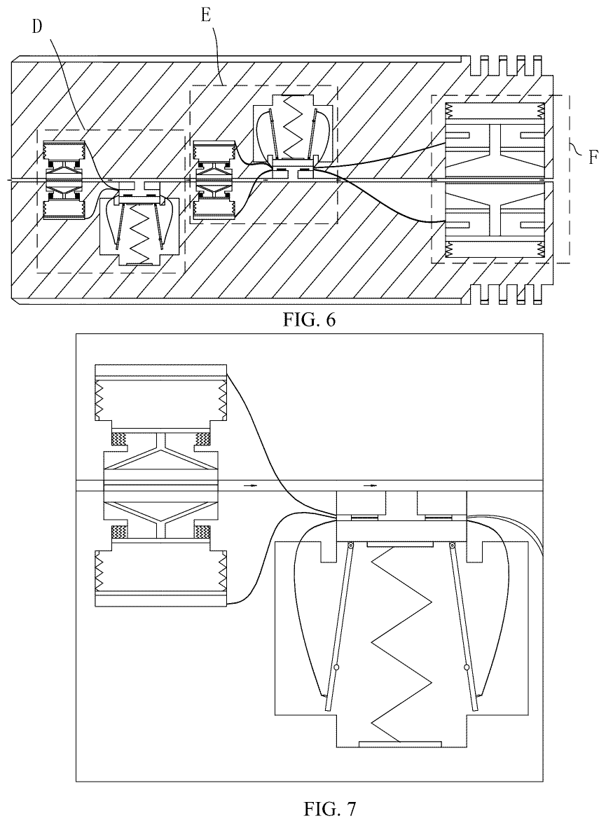

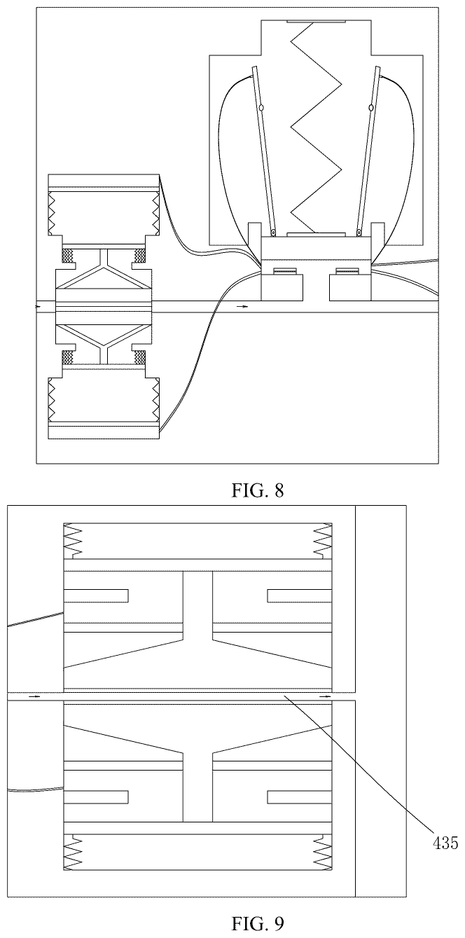

FIG. 3 is a partial enlarged schematic diagram of portion A shown in FIG. 2. FIG. 4 is a partial enlarged schematic diagram of portion B shown in FIG. 2. FIG. 5 is a partial enlarged schematic diagram of portion C shown in FIG. 2. FIG. 6 is a cross-sectional schematic diagram of an encapsulated water discharge device in a discharge state according to an embodiment of the present application. FIG. 7 is a partial enlarged schematic diagram of portion D shown in FIG. 6. FIG. 8 is a partial enlarged schematic diagram of portion E shown in FIG. 6. FIG. 9 is a partial enlarged schematic diagram of portion F shown in FIG. 6. Referring to FIGS. 3 to 5 in combination, the first power assembly 230 further includes a first power tube 231. The second power assembly 240 further includes a second power tube 241 and a third power tube 242. The first pressure structure 310 controls the first engagement switch 300 to be opened or closed through the first power tube 231. The second pressure structure 410 controls the second engagement switch 400 to be opened or closed through the second power tube 241. The second pressure structure 410 controls the third engagement switch 430 to be opened or closed through the third power tube 242.

Specifically, the second accommodating chamber 540 includes a first cavity 542, a second cavity 543, and a third cavity 544 connected in sequence. The first pressure structure 310 includes a first fixing piece 311, a first piston air guide cushion 312, a first fixing plate 313, a first spring 314, a first electromagnet 315, and a first guide plate 316. The first fixing piece 311 is arranged in the first cavity 542, and is fixedly fitted with the first cavity 542 to form the first through hole 541. The first fixing plate 313 is arranged on the side of the first fixing piece 311 adjacent to the second cavity 543, and is slidably fitted with a cavity wall of the first cavity 542. The first piston air guide cushion 312 is arranged on the side of the first fixing piece 311 adjacent to the first fixing plate 313. The first guide plate 316 is arranged on the side of the first fixing plate 313 facing away from the first piston air guide cushion 312. A first power cavity 600 is formed between the first piston air guide cushion 312 and the first fixing plate 313. The first electromagnet 315 is arranged in the third cavity 544 and fixedly connected to a cavity wall of the third cavity 544. The first spring 314 is arranged in the second cavity 543. One end of the first spring 314 is connected to the first guide plate 316 and the other end is connected to the first electromagnet 315. The first power cavity 600 is connected to the first engagement switch 300 through the first power tube 231.

The fourth accommodating chamber 560 includes a fourth cavity 561, a fifth cavity 562 and a sixth cavity 563 connected in sequence. The second pressure structure 410 includes a second fixing piece 411, a second piston air guide cushion 412, a second fixing plate 413, a second spring 414, a second electromagnet 415, and a second guide plate 416. The second fixing piece 411 is arranged in the sixth cavity 563 and is fixedly fitted with the sixth cavity 563 to form the second through hole 555. The second fixing plate 413 is arranged on the side of the second fixing piece 411 adjacent to the fifth cavity 562 and is slidably fitted with a cavity wall of the sixth cavity 563. The second piston air guide cushion 412 is arranged on the side of the second fixing piece 411 adjacent to the second fixing plate 413. The second guide plate 416 is arranged on the side of the second fixing plate 413 facing away from the second piston air guide cushion 412. A second power cavity 610 is formed between the second piston air guide cushion 412 and the second fixing plate 413. The second electromagnet 415 is arranged in the fourth cavity 561 and fixedly connected to a cavity wall of the fourth cavity 561. The second spring 414 is arranged in the fifth cavity 562. One end of the second spring 414 is connected to the second guide plate 416, and the other end is connected to the second electromagnet 415. The second power cavity 610 is connected to the second engagement switch 400 through the second power tube 241. The second power cavity 610 is further connected to the third engagement switch 430 through the third power tube 242.

The first engagement switch 300 includes a first push piece 301, a first retractable piece 302, a second retractable piece 303, and a second push piece 304. The first retractable piece 302 and the second retractable piece 303 are arranged opposite to each other. The first push piece 301 is arranged on a side of the first retractable piece 302 facing away from the second retractable piece 303, and is fixedly connected to the first retractable piece 302. The second push piece 304 is arranged on a side of the second retractable piece 303 facing away from the first retractable piece 302, and is fixedly connected to the second retractable piece 303.

The first accommodating chamber 530 includes a first sub-chamber 531, a second sub-chamber 532, a third sub-chamber 533, and a fourth sub-chamber 534. The first push piece 301 is disposed in the first sub-chamber 531 and is slidably fitted with the first sub-chamber 531. The first retractable piece 302 is disposed in the second sub-chamber 532 and is slidably fitted with the second sub-chamber 532. The second retractable piece 303 is disposed in the third sub-chamber 533 and is slidably fitted with the third sub-chamber 533. The second push piece 304 is disposed in the fourth sub-chamber 534 and is slidably fitted with the fourth sub-chamber 534. The first power tube 231 includes a first sub-power tube 232 and a second sub-power tube 233. The first sub-chamber 531 is connected to the first power cavity 600 through the first sub-power tube 232. The fourth sub-chamber 534 is connected to the first power cavity 600 through the second sub-power tube 233.

The second engagement switch 400 includes a third push piece 401, a third retractable piece 402, a fourth retractable piece 403, and a fourth push piece 404. The third retractable piece 402 and the fourth retractable piece 403 are arranged opposite to each other. The third push piece 401 is arranged on the side of the third retractable piece 402 facing away from the fourth retractable piece 403, and is fixedly connected to the third retractable piece 402. The fourth push piece 404 is arranged on the side of the fourth retractable piece 403 facing away from the third retractable piece 402, and is fixedly connected to the third retractable piece 402.

The third accommodating chamber 550 includes a fifth sub-chamber 551, a sixth sub-chamber 552, a seventh sub-chamber 553, and an eighth sub-chamber 554. The third push piece 401 is disposed in the fifth sub-chamber 551 and is slidably fitted with the fifth sub-chamber 551. The third retractable piece 402 is disposed in the sixth sub-chamber 552 and is slidably fitted with the sixth sub-chamber 552. The fourth retractable piece 403 is disposed in the seventh sub-chamber 553 and is slidably fitted with the seventh sub-chamber 553. The fourth push piece 404 is disposed in the eighth sub-chamber 554 and is slidably fitted with the eighth sub-chamber 554. The second power tube 241 includes a third sub-power tube 243 and a fourth sub-power tube 244. The fifth sub-chamber 551 is connected to the second power cavity 610 through the third sub-power tube 243. The eighth sub-chamber 554 is connected to the second power cavity 610 through the fourth sub-power tube 244.

The third engagement switch 430 includes a fifth push piece 431, a fifth retractable piece 432, a sixth retractable piece 433, and a sixth push piece 434. The fifth retractable piece 432 and the sixth retractable piece 433 are arranged opposite to each other. The fifth push piece 431 is arranged on a side of the fifth retractable piece 432 facing away from the sixth retractable piece 433, and is fixedly connected to the sixth retractable piece 433. The sixth push piece 434 is arranged on the side of the sixth retractable piece 433 facing away from the fifth retractable piece 432, and is fixedly connected to the sixth retractable piece 433.

The fifth accommodating chamber 570 includes a ninth sub-chamber 571 and a tenth sub-chamber 572. The fifth push piece 431 and the fifth retractable piece 432 are both disposed in the ninth sub-chamber 571 and are slidably fitted with the ninth sub-chamber 571. The fifth push piece 431 is fitted with the ninth sub-chamber 571 to form a first push chamber 573. The sixth retractable piece 433 and the sixth push piece 434 are both disposed in the tenth sub-chamber 572 and are slidably fitted with the tenth sub-chamber 572. The sixth push piece 434 is fitted with the tenth sub-chamber 572 to form a second push chamber 574. The third power tube 242 includes a fifth sub-power tube 245 and a sixth sub-power tube 246. The first push chamber 573 is connected to the second power cavity 610 through the fifth sub-power tube 245. The second push chamber 574 is connected to the second power cavity 610 through the sixth sub-power tube 246.

Referring to FIGS. 2 to 9, when the sensor 910 detects that there is water vapor in the internal gas collection chamber 900, the first control module 221 controls to input a current to the first electromagnet 315, so that the first electromagnet 315 produces magnetism. The first guide plate 316 thus pushes the first spring 314 to move toward the first electromagnet, thereby driving the first fixing plate 313 to move along the walls of the first cavity 542 toward the first electromagnet, so that the first power cavity 600 forms a low-pressure state. The low pressure in the first power cavity 600 reaches the first sub-chamber 531 through the first sub-power tube 232. At this time, the first sub-chamber 531 also forms a low-pressure state, so that it cannot create a downward force on the first push piece 301, so that the first push piece 301 moves along the first sub-chamber 531 in a direction of getting farther away from the first retractable piece 302, and drives the first retractable piece 302 to move along the second sub-chamber 532 away from the second retractable piece 303. At the same time, the low pressure in the first power cavity 600 reaches the fourth sub-chamber 534 through the second sub-power tube 233. At this time, the fourth sub-chamber 534 also forms a low pressure state, so that it cannot form an upward force on the second push piece 304, so that the second push piece 304 moves along the fourth sub-chamber 534 away from the second retractable piece 303, and drives the second retractable piece 303 to move along the third sub-chamber 533 away from the first retractable piece 302. At this time, the first engagement switch 300 is opened to form the first air intake channel 305, so that the air inlet 250 and the first airflow channel 270 are connected through the first air intake channel 305 for air intake. The water vapor in the display panel 100 thus reaches the first power cavity 600 through the air inlet 250, the first engagement switch 300, and the first airflow channel 270. On the contrary, if the sensor 910 cannot detect the existence of water vapor in the display panel 100, the first control module 221 controls the power to be turned off. The first electromagnet 315 loses its magnetism. The first guide plate 316 and the first spring 314 are reset, driving the first fixing plate 313 to move away from the first electromagnet 315. At this time, the first power cavity 600 forms a high-pressure state, so that the high-pressure pressure reaches the first sub-chamber 531 through the first sub-power tube 232, forming a downward force on the first push piece 301, so that the first push piece 301 drives the first retractable piece 302 to move toward the second retractable piece 303. At the same time, the high-pressure pressure in the first power cavity 600 reaches the fourth sub-chamber 534 through the second sub-power tube 233, forming an upward force on the second push piece 304, so that the second push piece 304 drives the second retractable piece 303 to move toward the first retractable piece 302. At this time, the first engagement switch 300 is closed, and the first air intake channel 305 is closed. When the first fixing plate 313 moves away from the first electromagnet 315 to the first fixing piece 311, the first piston air guide cushion 312 presses against the first fixing piece 311, so that the first power cavity 600 connected to the first sub-power tube 232 and the second sub-power tube 233 has space and is not sealed. In addition, during the resetting and pushing process of the first fixing plate 313, the water vapor originally sucked into the first power cavity 600 is also discharged to the first airflow channel 270 through the first through hole 541.

At the same time, the second control module 222 controls a current to be supplied into the second electromagnet 415, so that the second electromagnet 415 produces magnetism. The second guide plate 416 pushes the second spring 414 to move toward the second electromagnet 415, thereby driving the second fixing plate 413 to move along the wall of the sixth cavity 563 toward the second electromagnet 415, so that the second power cavity 610 forms a low-pressure state. The low pressure in the second power cavity 610 reaches the fifth sub-chamber 551 through the third sub-power tube 243. At this time, the fifth sub-chamber 551 also forms a low-pressure state, so that it cannot create a downward force on the third push piece 401, so that the third push piece 401 moves along the fifth sub-chamber 551 away from the third retractable piece 402, and drives the third retractable piece 402 along the sixth sub-chamber 552 away from the fourth retractable piece 403. At the same time, the low pressure in the second power cavity 610 reaches the eighth sub-chamber 554 through the fourth sub-power tube 244. At this time, the eighth sub-chamber 554 also forms a low pressure state, so that it cannot form an upward force on the fourth push piece 404, so that the fourth push piece 404 moves along the eighth sub-chamber 554 away from the fourth retractable piece 403, and drives the fourth retractable piece 403 along the seventh sub-chamber 553 away from the third retractable piece 402. At this time, the second engagement switch 400 is opened to form the second air intake channel 405. The first airflow channel 270 is connected to the second airflow channel 280 through the second air intake channel 405 for air intake. The water vapor in the first airflow channel 270 reaches the second power cavity 610 through the second air intake channel 405 and the second airflow channel 280. When the water vapor in the first airflow channel 270 is discharged from the second engagement switch 400 to the second airflow channel 280, the second control module 222 controls the power to be turned off, so that the second electromagnet 415 loses its magnetism. The second guide plate 416 and the second spring 414 are reset, driving the second fixing plate 413 to move away from the second electromagnet 415. At this time, the second power cavity 610 forms a high-pressure state. Thus, the high pressure reaches the fifth sub-chamber 551 through the third sub-power tube 243, forming a downward force on the third push piece 401, so that the third push piece 401 drives the third retractable piece 402 to move toward the fourth retractable piece 403. At the same time, the high pressure in the second power cavity 610 reaches the eighth sub-chamber 554 through the fourth sub-power tube 244, forming an upward force on the fourth push piece 404, so that the fourth push piece 404 drives the fourth retractable piece 403 to move toward the third retractable piece 402. At this time, the second engagement switch 400 is closed, and the second air intake channel 405 is closed.

In addition, when the second power cavity 610 forms high pressure, part of the high pressure in the second power cavity 610 reaches the first push chamber 573 through the fifth sub-power tube 245, forming an upward force, thereby pushing the fifth push piece 431 to move along the ninth sub-chamber 571 in a direction away from the fifth retractable piece 432, and driving the fifth retractable piece 432 to move in the ninth sub-chamber 571 in a direction away from the sixth retractable piece 433. At the same time, part of the high pressure in the second power cavity 610 reaches the second push chamber 574 through the sixth sub-power tube 246, forming a downward force, thereby pushing the sixth push piece 434 to move along the tenth sub-chamber 572 in a direction away from the sixth retractable piece 433, and driving the sixth retractable piece 433 in the tenth sub-chamber 572 in a direction away from the fifth retractable piece 432. At this time, the third engagement switch 430 is opened to form the discharge channel 435, and discharges the water vapor in the second airflow channel 280 to the outside through the discharge channel 435 and the air outlet 260.

When the discharge is completed, the airflow at the second pressure structure 410 is almost evacuated, and a low pressure is formed at the second pressure structure 410. The low pressure reaches the first push chamber 573 through the fifth sub-power tube 245, forming a downward force, thereby driving the fifth push piece 431 to move along the ninth sub-chamber 571 toward the fifth retractable piece 432, and driving the fifth retractable piece 432 to move in the ninth sub-chamber 571 toward the sixth retractable piece 433. At the same time, a low pressure is formed at the second pressure structure 410 and reaches the second push chamber 574 through the sixth sub-power tube 246, forming an upward force, thereby driving the sixth push piece 434 to move along the tenth sub-chamber 572 toward the sixth retractable piece 433, and driving the sixth retractable piece 433 to move in the tenth sub-chamber 572 toward the fifth retractable piece 432, so that the third engagement switch 430 is closed.

As shown in FIG. 3 and FIG. 7, the first pressure structure 310 further includes a first auxiliary pressing rod 317, a second auxiliary pressing rod 318, a first fulcrum 319, a second fulcrum 320, a first auxiliary pressure pipe 321, a second auxiliary pressure pipe 322, a first pressure valve 323, and a second pressure valve 324. The first auxiliary pressing rod 317 and the second auxiliary pressing rod 318 are oppositely arranged in the second cavity 543. One end of the first auxiliary pressing rod 317 and one end of the second auxiliary pressing rod 318 are both movably connected to the side of the first fixing plate 313 facing away from the first piston air guide cushion 312. The other end of the first auxiliary pressing rod 317 and the other end of the second auxiliary pressing rod 318 respectively extend along the direction of pointing from the second cavity 543 to the third cavity 544. The first pressure valve 323 is arranged on the first auxiliary pressing rod 317. The second pressure valve 324 is arranged on the second auxiliary pressing rod 318. The first fulcrum 319 and the second fulcrum 320 are both fixedly arranged in the second cavity 543. The first auxiliary pressing rod 317 is connected to the first fulcrum 319. The second auxiliary pressing rod 318 is connected to the second fulcrum 320. The first power cavity 600 is connected to the first pressure valve 323 through the first auxiliary pressure pipe 321. The first power cavity 600 is connected to the second pressure valve 324 through the second auxiliary pressure pipe 322. In this way, when the first spring 314 and the first guide plate 316 reset and squeeze the gas in the first power cavity 600, the high pressure of the first power cavity 600 can reach the first pressure valve 323 through the first auxiliary pressure pipe 321, forming a force on the first auxiliary pressing rod 317, so that the first auxiliary pressing rod 317 presses against the first fulcrum 319 in the direction of approaching the second auxiliary pressing rod 318. Similarly, the high pressure of the first power cavity 600 can reach the second pressure valve 324 through the second auxiliary pressure pipe 322, forming a force on the second auxiliary pressing rod 318, so that the second auxiliary pressing rod 318 presses against the second fulcrum 320 in the direction of approaching the first auxiliary pressing rod 317. At this time, the first auxiliary pressing rod 317 and the second auxiliary pressing rod 318 simultaneously form an upward squeezing force on the first fixing plate 313, so that the first power cavity 600 transmits the high pressure to the first engagement switch 300, and the first engagement switch 300 is closed and pressed more tightly without air leakage.

Similarly, the second pressure structure 410 further includes a third auxiliary pressing rod 417, a fourth auxiliary pressing rod 418, a third fulcrum 419, a fourth fulcrum 420, a third auxiliary pressure pipe 421, a fourth auxiliary pressure pipe 422, a third pressure valve 423, and a fourth pressure valve 424. The third auxiliary pressing rod 417 and the fourth auxiliary pressing rod 418 are oppositely arranged in the fifth cavity 562. One end of the third auxiliary pressing rod 417 and one end of the fourth auxiliary pressing rod 418 are both movably connected to the side of the second fixing plate 413 facing away from the second piston air guide cushion 412. The other end of the third auxiliary pressing rod 417 and the other end of the fourth auxiliary pressing rod 418 respectively extend in the direction of pointing from the fifth cavity 562 to the sixth cavity 563. The third pressure valve 423 is arranged on the third auxiliary pressing rod 417. The fourth pressure valve 424 is arranged on the fourth auxiliary pressing rod 418. The third fulcrum 419 and the fourth fulcrum 420 are fixedly arranged in the second cavity 543. The third auxiliary pressing rod 417 is connected to the third fulcrum 419. The fourth auxiliary pressing rod 418 is connected to the fourth fulcrum 420. The second power cavity 610 is connected to the third pressure valve 423 through the third auxiliary pressure pipe 421. The second power cavity 610 is connected to the fourth pressure valve 424 through the fourth auxiliary pressure pipe 422. In this way, when the second spring 414 and the second guide plate 416 reset and squeeze the gas in the second power cavity 610, the high pressure of the second power cavity 610 can reach the third pressure valve 423 through the third auxiliary pressure pipe 421, forming a force on the third auxiliary pressing rod 417, so that the third auxiliary pressing rod 417 presses against the third fulcrum 419 in the direction of approaching the fourth auxiliary pressing rod 418. Similarly, the high pressure of the second power cavity 610 can reach the fourth pressure valve 424 through the fourth auxiliary pressure pipe 422, forming a force on the fourth auxiliary pressing rod 418, so that the fourth auxiliary pressing rod 418 presses against the fourth fulcrum 420 in the direction of approaching the third auxiliary pressing rod 417. At this time, the third auxiliary pressing rod 417 and the fourth auxiliary pressing rod 418 simultaneously form a downward squeezing force on the second fixing plate 413, so that the second power cavity 610 transmits the high pressure to the second engagement switch 400, and the second engagement switch 400 is closed and pressed more tightly without leaking.

As shown in FIG. 4, the first cavity 542 is fitted with the second cavity 543 to form a first protrusion 620 and a second protrusion 630. The first protrusion 620 is arranged on the side of the first auxiliary pressing rod 317 facing away from the second auxiliary pressing rod 318, and cooperates with the first auxiliary pressing rod 317 to limit the travel distance of the first auxiliary pressing rod 317. The second protrusion 630 is arranged on the side of the second auxiliary pressing rod 318 facing away from the first auxiliary pressing rod 317, and cooperates with the second auxiliary pressing rod 318 to limit the travel distance of the second auxiliary pressing rod 318. The fifth cavity 562 is fitted with the sixth cavity 563 to form a third protrusion 640 and a fourth protrusion 650. The third protrusion 640 is arranged on the side of the third auxiliary pressing rod 417 facing away from the fourth auxiliary pressing rod 418, and cooperates with the third auxiliary pressing rod 417 to limit the travel distance of the third auxiliary pressing rod 417. The fourth protrusion 650 is arranged on the side of the fourth auxiliary pressing rod 418 facing away from the third auxiliary pressing rod 417, and cooperates with the fourth auxiliary pressing rod 418 to limit the travel distance of the fourth auxiliary pressing rod 418. Thereby, when the first auxiliary pressing rod 317, the second auxiliary pressing rod 318, the third auxiliary pressing rod 417, and the fourth auxiliary pressing rod 418 are opened outward, the travel stops when they reach the corresponding protrusions, thereby limiting the travel of the first fixing plate 313 or the second fixing plate 413, so that the first fixing plate 313 slides in the first cavity 542 and the second fixing plate 413 slides in the sixth cavity 563.

In addition, the first engagement switch 300 and the second engagement switch 400 should be closed after the air intake is completed to prevent the water vapor that is sucked out from re-entering the display panel 100. Therefore, a plurality of small springs may be disposed between the first engagement switch 300 and the first cavity 542 for connection, so that the first engagement switch 300 has a longer stroke when opened, and the opened first air intake channel 305 will be relatively small, so that the airflow is more concentrated. Furthermore, when the first engagement switch 300 is closed after the air intake is completed, the travel distance is relatively short so that the closing is faster. At the same time, multiple small springs are respectively arranged between the second engagement switch 400 and the third cavity 544, and between the third engagement switch 430 and the fifth cavity 562 for connection. The working principle is the same as that between the first engagement switch 300 and the first cavity 542, so it will not be repeated here again.

As shown in FIG. 5, combined with FIG. 1, for the convenience of installation, the encapsulation and water vapor removal device 200 is a cylindrical structure. The substrate 110 includes a first fixing end 111 on one side adjacent to the encapsulation and water vapor removal device 200. The cover plate 130 includes a second fixing end 131 on one side adjacent to the encapsulation and water vapor removal device. An opening 700 is formed between the first fixing end 111 and the second fixing end 131. The encapsulation and water vapor removal device 200 is installed in the opening 700. The interior of the opening 700 defines a threaded groove. The outer wall of the encapsulation and water vapor removal device 200 includes a threaded structure matching the threaded groove. The encapsulation and water vapor removal device 200 can be installed at the opening 700. The first fixing piece 311 fixedly abuts against the first fixing end 111, and the second fixing piece 411 fixedly abuts against the second fixing end 131. The first fixing piece 311 includes a first sealing piece 710 on the side abutting against the second fixing end 131. The second fixing piece 411 includes a second sealing piece 800 on the side abutting against the first fixing end 111. The first sealing piece 710 and the second sealing piece 800 are both disposed away from the pixel module 120. The first sealing piece 710 includes a plurality of first sealing columns 720 arranged at intervals. The second sealing piece 800 includes a plurality of second sealing columns 810 arranged at intervals. A first sealing groove 730 is formed between every two adjacent first sealing columns 720. A second sealing groove 820 is formed between two adjacent second sealing columns 810.

The first sealing grooves 730 are all interconnected with each other. The second sealing grooves 820 are all interconnected with each other. The first sealing grooves 730 are connected to the second sealing grooves 820. The second fixing end 131 includes a fixing end body 132, an adhesive injection channel 133, and an adhesive injection port 134. The adhesive injection port 134 is arranged on the side of the fixing end body 132 facing away from the first sealing piece 710. The adhesive injection channel 133 penetrates the fixing end body 132. The adhesive injection port 134 is connected to the first first sealing groove 730 through the adhesive injection channel 133. In this way, after the encapsulation adhesive is injected into the adhesive injection port 134, the encapsulation adhesive can reach each first sealing groove 730 and each second sealing groove 820 through the adhesive injection channel 133, thereby sealing the air inlet channel between the encapsulation and water vapor removal device 200 and the opening 700, thus preventing external water vapor from entering the display panel 100 through the air inlet channel between the encapsulation and water vapor removal device 200 and the opening 700, which may otherwise affect the display panel 100.

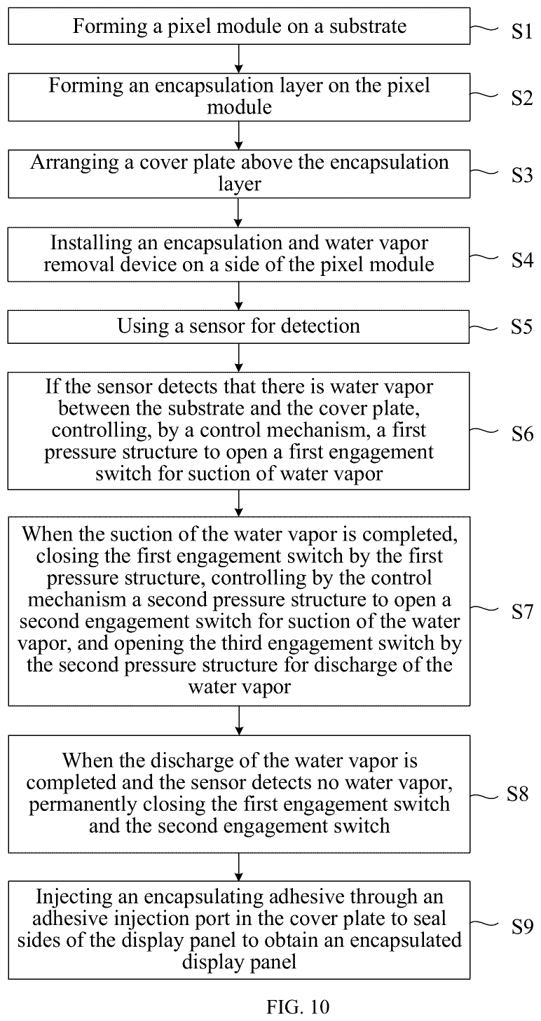

FIG. 10 is a schematic flowchart of an encapsulating method for a display panel according to the present application. As shown in FIG. 10, the present application further discloses an encapsulating method for a display panel, including the following operations:
S1: forming a pixel module on a substrate;
S2: forming an encapsulation layer on the pixel module;
S3: disposing a cover plate above the encapsulation layer;
S4: installing an encapsulation and water vapor removal device on a side of the pixel module;
S5: using a sensor for detection;
S6: if the sensor detects that there is water vapor between the substrate and the cover plate, a control mechanism controlling a first pressure structure to open the first engagement switch for suction;
S7: after the suction is completed, the first pressure structure closing the first engagement switch, the control mechanism controlling the second pressure structure to open the second engagement switch for suction, and the second pressure structure opening the third engagement switch for discharge;
S8: after the discharge is completed, when the sensor cannot detect water vapor, permanently closing the first engagement switch and the second engagement switch;
S9: injecting an encapsulation adhesive from the adhesive injection port in the cover plate to seal the sides of the display panel to obtain an encapsulated display panel.

By encapsulating the display panel 100 using the above encapsulating method, the water vapor in the display panel 100 can be discharged, the possibility of the presence of water vapor in the display panel 100 can be reduced, and the pixel module 120 can be further protected.

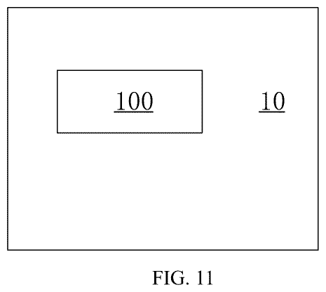

FIG. 11 is a block diagram of a display device according to an embodiment of the present application. As shown in FIG. 11, the present application further discloses a display device 10, which uses the display panel 100 as described above. The display device 10 assembled in this way reduces the impact of water vapor on the pixel module 120, and can ensure the display effect and extend the service life.

It should be noted that the limitations of the various steps involved in this solution are not to be interpreted to limit the order of the steps, under the premise of not affecting the implementation of the specific solution. The steps written earlier can be executed first, or later, or even at the same time with the steps written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. An encapsulation and water vapor removal device for a display panel, wherein the display panel comprises a substrate, a pixel module, and a cover plate; wherein the pixel module is arranged on the substrate, wherein the cover plate is arranged on a side of the pixel module facing away from the substrate;
wherein the encapsulation and water vapor removal device is arranged on a side of the pixel module; wherein the encapsulation and water vapor removal device is used to remove water vapor between the substrate and the cover plate, and inject a sealant to seal sides of the substrate and the cover plate to obtain an encapsulated display panel after discharging the water vapor.

2. The encapsulation and water vapor removal device as recited in claim 1, wherein the encapsulation and water vapor removal device comprises an air intake and discharge device and a control mechanism; wherein the air intake and discharge device comprises a first power assembly, a second power assembly, an air inlet, and an air outlet; wherein the air inlet is arranged on a side of the air intake and discharge device facing towards the pixel module, wherein the air outlet is arranged on a side of the air intake and discharge device facing away from the air inlet; wherein the second power assembly is arranged between the first power assembly and the air outlet; wherein the control mechanism is arranged on one side of the air intake and discharge device and is in a signal connection with each of the first power assembly and the second power assembly separately;
wherein when the air intake and discharge device is in an air intake state, the control mechanism is configured to control the first power assembly to suck in air from between the substrate and the cover plate through the air inlet; wherein when the air intake and discharge device is in a discharge state, the control mechanism is configured to control the second power assembly to discharge the air containing water vapor to an outside of the air intake and discharge device facing away from the display panel.

3. The encapsulation and water vapor removal device as recited in claim 2, wherein the air intake and discharge device further comprises a first airflow channel, a second airflow channel, and a third airflow channel that are arranged in sequence; wherein the first power assembly comprises a first engagement switch and a first pressure structure; wherein the second power assembly comprises a second engagement switch, a second pressure structure, and a third engagement switch; wherein the first engagement switch is arranged on a side of the air intake and discharge device facing towards the pixel module, wherein the third engagement switch is arranged on a side of the air intake and discharge device facing towards the air outlet; wherein the second engagement switch is arranged between the first engagement switch and the third engagement switch;
wherein the first pressure structure is arranged between the first engagement switch and the second engagement switch; wherein the second pressure structure is arranged between the second engagement switch and the third engagement switch;
wherein the air inlet is connected to the second airflow channel through the first airflow channel and the first engagement switch; wherein one end of the third airflow channel is connected to the second airflow channel through the second engagement switch, and another end of the third airflow channel is connected to the air outlet through the third engagement switch;
wherein the control mechanism is configured to control the first pressure structure to drive the first engagement switch to be opened or closed; wherein the control mechanism is further configured to control the second pressure structure to drive the second engagement switch and the third engagement switch to be opened or closed.

4. The encapsulation and water vapor removal device as recited in claim 3, further comprising a fixing structure, wherein the fixing structure comprises a first fixing seat and a second fixing seat, wherein the first fixing seat is arranged opposite to the second fixing seat to define the first airflow channel, the second airflow channel, and the third airflow channel; wherein the first fixing seat and the second fixing seat each comprise a plurality of grooves, wherein the plurality of grooves of the first fixing seat are arranged oppositely and correspondingly to the plurality of grooves of the second fixing seat to define a first accommodating chamber, a second accommodating chamber, a third accommodating chamber, a fourth accommodating chamber, and a fifth accommodating chamber;
wherein the first engagement switch is arranged in the first accommodating chamber; wherein the first pressure structure is arranged in the second accommodating chamber and is communicated to the second airflow channel through a first through hole; wherein the second engagement switch is arranged in the third accommodating chamber; wherein the second pressure structure is arranged in the fourth accommodating chamber and is communicated to the third airflow channel through a second through hole; wherein the third engagement switch is arranged in the fifth accommodating chamber;
wherein the first power assembly further comprises a first power tube; wherein the second power assembly further comprises a second power tube and a third power tube; wherein the first pressure structure is operative to control the first engagement switch to be opened or closed through the first power tube; wherein the second pressure structure is operative to control the second engagement switch to be opened or closed through the second power tube; wherein the second pressure structure is further operative to control the third engagement switch to be opened or closed through the third power tube.

5. The encapsulation and water vapor removal device as recited in claim 4, wherein the second accommodating chamber comprises a first cavity, a second cavity, and a third cavity that are connected in sequence; wherein the first pressure structure comprises a first fixing piece, a first piston air guide cushion, a first fixing plate, a first spring, a first electromagnet, and a first guide plate; wherein the first fixing piece is arranged in the first cavity and fixedly fitted with the first cavity to define the first through hole; wherein the first fixing plate is arranged on a side of the first fixing piece facing towards the second cavity and is slidably fitted with a cavity wall of the first cavity; wherein the first piston air guide cushion is arranged on a side of the first fixing piece facing towards the first fixing plate; wherein the first guide plate is arranged on a side of the first fixing plate facing away from the first piston air guide cushion; wherein there is defined a first power cavity formed between the first piston air guide cushion and the first fixing plate;
wherein the first electromagnet is arranged in the third cavity and fixedly connected to a cavity wall of the third cavity; wherein the first spring is arranged in the second cavity, and wherein one end of the first spring is connected to the first guide plate, and another end is connected to the first electromagnet; wherein the first power cavity is connected to the first engagement switch through the first power tube;
wherein the fourth accommodating chamber comprises a fourth cavity, a fifth cavity, and a sixth cavity that are connected in sequence; wherein the second pressure structure comprises a second fixing piece, a second piston air guide cushion, a second fixing plate, a second spring, a second electromagnet, and a second guide plate; wherein the second fixing piece is arranged in the sixth cavity and fixedly fitted with the sixth cavity to define a second through hole; wherein the second fixing plate is arranged on a side of the second fixing piece facing towards the fifth cavity and is slidably fitted with a cavity wall of the sixth cavity; wherein the second piston air guide cushion is arranged on a side of the second fixing piece facing towards the second fixing plate; wherein the second guide plate is arranged on a side of the second fixing plate facing away from the second piston air guide cushion; wherein there is defined a second power cavity between the second piston air guide cushion and the second fixing plate;
wherein the second electromagnet is arranged in the fourth cavity and fixedly connected to a cavity wall of the fourth cavity, wherein the second spring is arranged in the fifth cavity, and wherein one end of the second spring is connected to the second guide plate, and another end is connected to the second electromagnet; wherein the second power cavity is connected to the second engagement switch through the second power tube; wherein the second power cavity is further connected to the third engagement switch through the third power tube.

6. The encapsulation and water vapor removal device as recited in claim 4, wherein the first engagement switch comprises a first push piece, a first retractable piece, a second retractable piece, and a second push piece; wherein the first retractable piece and the second retractable piece are arranged opposite to each other; wherein the first push piece is arranged on a side of the first retractable piece facing away from the second retractable piece, and is fixedly connected to the first retractable piece; wherein the second push piece is arranged on a side of the second retractable piece facing away from the first retractable piece, and is fixedly connected to the second retractable piece;
wherein the first accommodating chamber comprises a first sub-chamber, a second sub-chamber, a third sub-chamber, and a fourth sub-chamber; wherein the first push piece is arranged in the first sub-chamber and is slidably fitted with the first sub-chamber; wherein the first retractable piece is arranged in the second sub-chamber and is slidably fitted with the second sub-chamber; wherein the second retractable piece is arranged in the third sub-chamber and is slidably fitted with the third sub-chamber; wherein the second push piece is arranged in the fourth sub-chamber and is slidably fitted with the fourth sub-chamber;
wherein the first power tube comprises a first sub-power tube and a second sub-power tube; wherein the first sub-chamber is connected to the first power chamber through the first sub-power tube; wherein the fourth sub-chamber is connected to the first power chamber through the second sub-power tube;
wherein the second matching switch comprises a third push piece, a third retractable piece, a fourth retractable piece, and a fourth push piece; wherein the third retractable piece and the fourth retractable piece are arranged opposite to each other; wherein the third push piece is arranged on a side of the third retractable piece facing away from the fourth retractable piece, and is fixedly connected to the third retractable piece; wherein the fourth push piece is arranged on a side of the fourth retractable piece facing away from the third retractable piece, and is fixedly connected to the third retractable piece;
wherein the third accommodating chamber comprises a fifth sub-chamber, a sixth sub-chamber, a seventh sub-chamber, and an eighth sub-chamber; wherein the third push piece is arranged in the fifth sub-chamber, and is slidably fitted with the fifth sub-chamber; wherein the third retractable piece is arranged in the sixth sub-chamber, and is slidably fitted with the sixth sub-chamber; wherein the fourth retractable piece is arranged in the seventh sub-chamber and is slidably fitted with the seventh sub-chamber; wherein the fourth push piece is arranged in the eighth sub-chamber and is slidably fitted with the eighth sub-chamber; wherein the second power tube comprises a third sub-power tube and a fourth sub-power tube; wherein the fifth sub-chamber is connected to the second power chamber through the third sub-power tube; the eighth sub-chamber is connected to the second power chamber through the fourth sub-power tube;
wherein the third matching switch comprises a fifth push piece, a fifth retractable tube, a sixth retractable piece, and a sixth push piece; wherein the fifth retractable piece and the sixth retractable piece are arranged opposite to each other; wherein the fifth push piece is arranged on a side of the fifth retractable piece facing away from the sixth retractable piece, and is fixedly connected to the sixth retractable piece; wherein the sixth push piece is arranged on a side of the sixth retractable piece facing away from the fifth retractable piece, and is fixedly connected to the sixth retractable piece;
wherein the fifth accommodating chamber comprises a ninth sub-chamber and a tenth sub-chamber; wherein the fifth push piece and the fifth retractable piece are both arranged in the ninth sub-chamber and are each slidably fitted with the ninth sub-chamber; wherein the fifth push piece is fitted with the ninth sub-chamber to form a first push chamber; wherein the sixth retractable piece and the sixth push piece are both arranged in the tenth sub-chamber and are each slidably fitted with the tenth sub-chamber; wherein the sixth push piece is fitted with the tenth sub-chamber to form a second push chamber; wherein the third power tube comprises a fifth sub-power tube and a sixth sub-power tube; wherein the first push chamber is connected to the second power chamber through the fifth sub-power tube, and wherein the second push chamber is connected to the second power chamber through the sixth sub-power tube.

7. The encapsulation and water vapor removal device as recited in claim 5, wherein the first pressure structure further comprises a first auxiliary assembly, which is arranged in the second accommodating chamber and pressed against the first fixing plate; wherein the second pressure structure further comprises a second auxiliary assembly, which is arranged in the fourth accommodating chamber and pressed against the second fixing plate.

8. The encapsulation and water vapor removal device as recited in claim 1, wherein the encapsulation and water vapor removal device is a cylindrical structure; wherein the substrate comprises a first fixing end on a side facing towards the encapsulation and water vapor removal device; wherein the cover plate comprises a second fixing end on a side facing towards the encapsulation and water vapor removal device; wherein there is formed an opening between the first fixing end and the second fixing end; wherein the encapsulation and water vapor removal device is installed in the opening, wherein the first fixing piece fixedly abuts against the first fixing end, and wherein the second fixing piece fixedly abuts against the second fixing end;
wherein the first fixing piece comprises a first sealing piece at a side where the first fixing piece abuts against the second fixing end; wherein the second fixing piece comprises a second sealing piece at a side where the second fixing piece abuts against the first fixing end; wherein the first sealing piece is communicated to the second sealing piece; wherein the second fixing end comprises a fixing end body, an adhesive injection channel, and an adhesive injection port; wherein the adhesive injection port is defined in a side of the fixing end body facing away from the first sealing piece; wherein the adhesive injection channel penetrates through the fixing end body, and wherein the adhesive injection port is connected to the first sealing piece through the adhesive injection channel.

9. An encapsulating method for a display panel, the display panel comprising a substrate, a pixel module, and a cover plate; wherein the pixel module is arranged on the substrate, wherein the cover plate is arranged on a side of the pixel module facing away from the substrate, wherein the encapsulating method comprises:
forming the pixel module on the substrate;
forming an encapsulation layer on the pixel module;
arranging a cover plate above the encapsulation layer;
installing an encapsulation and water vapor removal device on a side of the pixel module, the encapsulation and water vapor removal device being used to remove water vapor present between the substrate and the cover plate;
using a sensor for detection;
in response to the sensor detecting that there is water vapor between the substrate and the cover plate, controlling, by a control mechanism of the encapsulation and water vapor removal device, a first pressure structure of the encapsulation and water vapor removal device to open a first engagement switch of the encapsulation and water vapor removal device for suction of the water vapor;
in response to the suction of the water vapor being completed, closing the first engagement switch by the first pressure structure, controlling by the control mechanism a second pressure structure of the encapsulation and water vapor removal device to open a second engagement switch of the encapsulation and water vapor removal device for suction of the water vapor, and opening the third engagement switch by the second pressure structure for discharge of the water vapor;
in response to the discharge of the water vapor being completed and the sensor detecting no water vapor, permanently closing the first engagement switch and the second engagement switch;
injecting an encapsulating adhesive through the adhesive injection port in the cover plate to seal sides of the display panel to obtain an encapsulated display panel.

10. A display device, comprising a display panel, the display panel comprising a substrate, a pixel module, and a cover plate; wherein the pixel module is arranged on the substrate, wherein the cover plate is arranged on a side of the pixel module facing away from the substrate;
wherein the encapsulation and water vapor removal device is arranged on a side of the pixel module; wherein the encapsulation and water vapor removal device is used to remove water vapor between the substrate and the cover plate, and inject a sealant to seal sides of the substrate and the cover plate to obtain an encapsulated display panel after discharging the water vapor.

11. The display device as recited in claim 10, wherein the encapsulation and water vapor removal device comprises an air intake and discharge device and a control mechanism; wherein the air intake and discharge device comprises a first power assembly, a second power assembly, an air inlet, and an air outlet; wherein the air inlet is arranged on a side of the air intake and discharge device facing towards the pixel module, wherein the air outlet is arranged on a side of the air intake and discharge device facing away from the air inlet; wherein the second power assembly is arranged between the first power assembly and the air outlet; wherein the control mechanism is arranged on one side of the air intake and discharge device and is in a signal connection with each of the first power assembly and the second power assembly separately;
wherein when the air intake and discharge device is in an air intake state, the control mechanism is configured to control the first power assembly to suck in air from between the substrate and the cover plate through the air inlet; wherein when the air intake and discharge device is in a discharge state, the control mechanism is configured to control the second power assembly to discharge the air containing water vapor to an outside of the air intake and discharge device facing away from the display panel.

12. The display device as recited in claim 11, wherein the air intake and discharge device further comprises a first airflow channel, a second airflow channel, and a third airflow channel that are arranged in sequence; wherein the first power assembly comprises a first engagement switch and a first pressure structure; wherein the second power assembly comprises a second engagement switch, a second pressure structure, and a third engagement switch; wherein the first engagement switch is arranged on a side of the air intake and discharge device facing towards the pixel module, wherein the third engagement switch is arranged on a side of the air intake and discharge device facing towards the air outlet; wherein the second engagement switch is arranged between the first engagement switch and the third engagement switch;
wherein the first pressure structure is arranged between the first engagement switch and the second engagement switch; wherein the second pressure structure is arranged between the second engagement switch and the third engagement switch;
wherein the air inlet is connected to the second airflow channel through the first airflow channel and the first engagement switch; wherein one end of the third airflow channel is connected to the second airflow channel through the second engagement switch, and another end of the third airflow channel is connected to the air outlet through the third engagement switch;
wherein the control mechanism is configured to control the first pressure structure to drive the first engagement switch to be opened or closed; wherein the control mechanism is further configured to control the second pressure structure to drive the second engagement switch and the third engagement switch to be opened or closed.

13. The display device as recited in claim 12, wherein the encapsulation and water vapor removal device further comprises a fixing structure, wherein the fixing structure comprises a first fixing seat and a second fixing seat, wherein the first fixing seat is arranged opposite to the second fixing seat to define the first airflow channel, the second airflow channel, and the third airflow channel; wherein the first fixing seat and the second fixing seat each comprise a plurality of grooves, wherein the plurality of grooves of the first fixing seat are arranged oppositely and correspondingly to the plurality of grooves of the second fixing seat to define a first accommodating chamber, a second accommodating chamber, a third accommodating chamber, a fourth accommodating chamber, and a fifth accommodating chamber;
wherein the first engagement switch is arranged in the first accommodating chamber; wherein the first pressure structure is arranged in the second accommodating chamber and is communicated to the second airflow channel through a first through hole; wherein the second engagement switch is arranged in the third accommodating chamber; wherein the second pressure structure is arranged in the fourth accommodating chamber and is communicated to the third airflow channel through a second through hole; wherein the third engagement switch is arranged in the fifth accommodating chamber;
wherein the first power assembly further comprises a first power tube; wherein the second power assembly further comprises a second power tube and a third power tube; wherein the first pressure structure is operative to control the first engagement switch to be opened or closed through the first power tube; wherein the second pressure structure is operative to control the second engagement switch to be opened or closed through the second power tube; wherein the second pressure structure is further operative to control the third engagement switch to be opened or closed through the third power tube.

14. The display device as recited in claim 13, wherein the second accommodating chamber comprises a first cavity, a second cavity, and a third cavity that are connected in sequence; wherein the first pressure structure comprises a first fixing piece, a first piston air guide cushion, a first fixing plate, a first spring, a first electromagnet, and a first guide plate; wherein the first fixing piece is arranged in the first cavity and fixedly fitted with the first cavity to define the first through hole; wherein the first fixing plate is arranged on a side of the first fixing piece facing towards the second cavity and is slidably fitted with a cavity wall of the first cavity; wherein the first piston air guide cushion is arranged on a side of the first fixing piece facing towards the first fixing plate; wherein the first guide plate is arranged on a side of the first fixing plate facing away from the first piston air guide cushion; wherein there is defined a first power cavity formed between the first piston air guide cushion and the first fixing plate;
wherein the first electromagnet is arranged in the third cavity and fixedly connected to a cavity wall of the third cavity; wherein the first spring is arranged in the second cavity, and wherein one end of the first spring is connected to the first guide plate, and another end is connected to the first electromagnet; wherein the first power cavity is connected to the first engagement switch through the first power tube;
wherein the fourth accommodating chamber comprises a fourth cavity, a fifth cavity, and a sixth cavity that are connected in sequence; wherein the second pressure structure comprises a second fixing piece, a second piston air guide cushion, a second fixing plate, a second spring, a second electromagnet, and a second guide plate; wherein the second fixing piece is arranged in the sixth cavity and fixedly fitted with the sixth cavity to define a second through hole; wherein the second fixing plate is arranged on a side of the second fixing piece facing towards the fifth cavity and is slidably fitted with a cavity wall of the sixth cavity; wherein the second piston air guide cushion is arranged on a side of the second fixing piece facing towards the second fixing plate; wherein the second guide plate is arranged on a side of the second fixing plate facing away from the second piston air guide cushion; wherein there is defined a second power cavity between the second piston air guide cushion and the second fixing plate;
wherein the second electromagnet is arranged in the fourth cavity and fixedly connected to a cavity wall of the fourth cavity, wherein the second spring is arranged in the fifth cavity, and wherein one end of the second spring is connected to the second guide plate, and another end is connected to the second electromagnet; wherein the second power cavity is connected to the second engagement switch through the second power tube; wherein the second power cavity is further connected to the third engagement switch through the third power tube.

15. The display device as recited in claim 13, wherein the first engagement switch comprises a first push piece, a first retractable piece, a second retractable piece, and a second push piece; wherein the first retractable piece and the second retractable piece are arranged opposite to each other; wherein the first push piece is arranged on a side of the first retractable piece facing away from the second retractable piece, and is fixedly connected to the first retractable piece; wherein the second push piece is arranged on a side of the second retractable piece facing away from the first retractable piece, and is fixedly connected to the second retractable piece;
wherein the first accommodating chamber comprises a first sub-chamber, a second sub-chamber, a third sub-chamber, and a fourth sub-chamber; wherein the first push piece is arranged in the first sub-chamber and is slidably fitted with the first sub-chamber; wherein the first retractable piece is arranged in the second sub-chamber and is slidably fitted with the second sub-chamber; wherein the second retractable piece is arranged in the third sub-chamber and is slidably fitted with the third sub-chamber; wherein the second push piece is arranged in the fourth sub-chamber and is slidably fitted with the fourth sub-chamber;
wherein the first power tube comprises a first sub-power tube and a second sub-power tube; wherein the first sub-chamber is connected to the first power chamber through the first sub-power tube; wherein the fourth sub-chamber is connected to the first power chamber through the second sub-power tube;
wherein the second matching switch comprises a third push piece, a third retractable piece, a fourth retractable piece, and a fourth push piece; wherein the third retractable piece and the fourth retractable piece are arranged opposite to each other; wherein the third push piece is arranged on a side of the third retractable piece facing away from the fourth retractable piece, and is fixedly connected to the third retractable piece; wherein the fourth push piece is arranged on a side of the fourth retractable piece facing away from the third retractable piece, and is fixedly connected to the third retractable piece;
wherein the third accommodating chamber comprises a fifth sub-chamber, a sixth sub-chamber, a seventh sub-chamber, and an eighth sub-chamber; wherein the third push piece is arranged in the fifth sub-chamber, and is slidably fitted with the fifth sub-chamber; wherein the third retractable piece is arranged in the sixth sub-chamber, and is slidably fitted with the sixth sub-chamber; wherein the fourth retractable piece is arranged in the seventh sub-chamber and is slidably fitted with the seventh sub-chamber; wherein the fourth push piece is arranged in the eighth sub-chamber and is slidably fitted with the eighth sub-chamber; wherein the second power tube comprises a third sub-power tube and a fourth sub-power tube; wherein the fifth sub-chamber is connected to the second power chamber through the third sub-power tube; the eighth sub-chamber is connected to the second power chamber through the fourth sub-power tube;
wherein the third matching switch comprises a fifth push piece, a fifth retractable tube, a sixth retractable piece, and a sixth push piece; wherein the fifth retractable piece and the sixth retractable piece are arranged opposite to each other; wherein the fifth push piece is arranged on a side of the fifth retractable piece facing away from the sixth retractable piece, and is fixedly connected to the sixth retractable piece; wherein the sixth push piece is arranged on a side of the sixth retractable piece facing away from the fifth retractable piece, and is fixedly connected to the sixth retractable piece;
wherein the fifth accommodating chamber comprises a ninth sub-chamber and a tenth sub-chamber; wherein the fifth push piece and the fifth retractable piece are both arranged in the ninth sub-chamber and are each slidably fitted with the ninth sub-chamber; wherein the fifth push piece is fitted with the ninth sub-chamber to form a first push chamber; wherein the sixth retractable piece and the sixth push piece are both arranged in the tenth sub-chamber and are each slidably fitted with the tenth sub-chamber; wherein the sixth push piece is fitted with the tenth sub-chamber to form a second push chamber; wherein the third power tube comprises a fifth sub-power tube and a sixth sub-power tube; wherein the first push chamber is connected to the second power chamber through the fifth sub-power tube, and wherein the second push chamber is connected to the second power chamber through the sixth sub-power tube.

16. The display device as recited in claim 14, wherein the first pressure structure further comprises a first auxiliary assembly, which is arranged in the second accommodating chamber and pressed against the first fixing plate; wherein the second pressure structure further comprises a second auxiliary assembly, which is arranged in the fourth accommodating chamber and pressed against the second fixing plate.

17. The display device as recited in claim 10, wherein the encapsulation and water vapor removal device is a cylindrical structure; wherein the substrate comprises a first fixing end on a side facing towards the encapsulation and water vapor removal device; wherein the cover plate comprises a second fixing end on a side facing towards the encapsulation and water vapor removal device; wherein there is formed an opening between the first fixing end and the second fixing end; wherein the encapsulation and water vapor removal device is installed in the opening, wherein the first fixing piece fixedly abuts against the first fixing end, and wherein the second fixing piece fixedly abuts against the second fixing end;
wherein the first fixing piece comprises a first sealing piece at a side where the first fixing piece abuts against the second fixing end; wherein the second fixing piece comprises a second sealing piece at a side where the second fixing piece abuts against the first fixing end; wherein the first sealing piece is communicated to the second sealing piece; wherein the second fixing end comprises a fixing end body, an adhesive injection channel, and an adhesive injection port; wherein the adhesive injection port is defined in a side of the fixing end body facing away from the first sealing piece; wherein the adhesive injection channel penetrates through the fixing end body, and wherein the adhesive injection port is connected to the first sealing piece through the adhesive injection channel.
